(19) United States
(12) Patent Application Publication
(10) Pub. No.: US 2007/0206700 A1
(43) Pub. Date: Sep. 6, 2007

(54) Quadrature Amplitude Modulation receiver and diagnostic method thereof

(75) Inventors: Chiao-Chih Chang, Taipei City (TW); Yih-Ming Tsuie, Hsinchu (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Mediatek Inc.

(21) Appl. No.: 11/369,094

(22) Filed: Mar. 6, 2006

(51) Int. Cl. H03C 5/00

(52) U.S. Cl. 375/269

(57) ABSTRACT

A Quadrature Amplitude Modulation (QAM) receiver is provided to demodulate received symbols into a constellation, and comprises a radio frequency (RF) module, an analog to digital converter (ADC), an auto gain controller (AGC), a digital modulator, a distribution analyzer and a system controller. The RF module receives and demodulates radio signals into received symbols. The ADC coupled to the RF module generates digital signals from the received symbols. The AGC normalizes signal amplitudes in the RF module. The digital demodulator performs synchronization and equalization to decode the digital signals, whereby a constellation is generated. The distribution analyzer coupled to the output of the ADC and the digital demodulator provides a decision grid to analyze the constellation. The system controller is coupled to the distribution analyzer, adjusting the AGC and digital demodulator according to the constellation analysis.

### BACKGROUND OF THE INVENTION

1. Field of the Invention

The invention relates to Quadrature Amplitude Modulation (QAM), and in particular, to a diagnostic method for demodulation correction utilizing constellation analysis.

2. Description of the Related Art

Quadrature Amplitude Modulation (QAM) uses different phases known as states: 16, 64, and 256. Each state is defined by a specific amplitude and phase. This means the generation and detection of symbols is more complex than a simple phase or amplitude device. The number of states per symbol is increased as total data size and bandwidth increase. The modulation schemes shown occupy the same bandwidth (after filtering), but provide varied efficiency (in theory at least).

FIG. 1 shows a conventional QAM receiver. Transmitted signals are received via an antenna 102 and processed in an RF module 104, thus received symbols are sent to the ADC 106. A digital demodulator 120 comprises various hardware diagrams (not shown) performing timing recovery, carrier recovery and equalization on the digital signals output from the ADC 106, and an equalized result is output therefrom for further forward error correction (FEC), such as trellis decoding and RS decoding. An AGC 110 is employed to adjust signal amplifications in the RF module 104 based on a control signal generated by the digital demodulator 120. All of the components described are essential parts required for a QAM receiver, and detailed implementation may vary with different vendors and devices, therefore detailed introductions are omitted herefrom.

Constellation diagrams are used to graphically represent the quality and distortion of a digital signal. FIG. 2 shows an ideal 64-QAM constellation distributed in a decision grid. The 64-QAM constellation comprises 64 spots 210 distributed in 64 cells of a decision grid 200. The decision grid 200 is a logical coordinate formed by an inphase axis crossing a quadrature axis that categorizes the constellation into digital values. Ideally, each received symbol output from the RF module 104 is mapped to a spot 210 in the constellation after demodulation, such that a corresponding digital value can be obtained for further decoding. In practice, a combination of modulation errors may be difficult to separate and identify, and, as such, it is necessary to evaluate the measured constellation diagrams using mathematical and statistical methods.

FIG. 3a to 3d show various erroneous symptoms of the constellation generated by the conventional QAM receiver. FIG. 3a shows a relatively rotating constellation 310 with respect to the decision grid 200 coordinate. When the digital demodulator 120 fails to compensate timing or carrier offsets, the QAM receiver 100 is not synchronized with the transmitter (not shown) and the rotation thus occurs. FIG. 3b shows an over-amplified constellation 320 and an under-amplified constellation 325 with respect to the decision grid 200 coordinate. When the AGC 110 fails to correctly normalize the power of received symbols in the RF module 104, the constellation increases or reduces its area scale. FIG. 3c shows an offset constellation 330 caused by a DC offset in the QAM receiver 100. The cause of DC offset may be signal noise or circuit malfunction. FIG. 3d shows a spot 210 of radius r, a statistical accumulation of corresponding inphase/quadrature values. The value of radius r is proportional to the SNR of received signals. As an example, an ideal transmission without noise will generate a dot having exceedingly small radius, whereas a high noise signal may result in a large spot 210 that overlaps the cell boundary of the decision grid 200, rendering digital values undistinguishable.

Since the foregoing symptoms are observable in the constellation, it is desirable to provide a diagnostic method detecting failure points of a QAM receiver.

### BRIEF SUMMARY OF THE INVENTION

An exemplary embodiment of a Quadrature Amplitude Modulation (QAM) receiver is provided, enabling demodulation of received symbols into a constellation, and comprising a radio frequency (RF) module, an analog to digital converter (ADC), an auto gain controller (AGC), a digital modulator, a distribution analyzer and a system controller. The RF module receives and demodulates radio signals into received symbols. The ADC, coupled to the RF module, generates digital signals from the received symbols. The AGC normalizes signal amplitudes in the RF module. The digital demodulator performs synchronization and equalization to decode the digital signals, such that a constellation is generated. The distribution analyzer coupled to the output of the ADC and the digital demodulator, provides a decision grid to analyze the constellation. The system controller is coupled to the distribution analyzer, adjusting the AGC and digital demodulator according to the constellation analysis.

The distribution analyzer determines whether the constellation is rotating by the decision grid, and SNR of the received symbols according to the constellation analysis. The distribution analyzer also determines whether the gain of the received symbols is correct, and whether a DC offset occurs according to the constellation analysis. The decision grid is a square comprising a plurality of cells, each corresponding to a digital value, in which a coordinate is formed by a horizontal axis crossing a vertical axis at the square center to generate four partitions as for quadrants. The horizontal axis denotes inphase components of the received symbol, and the vertical axis denotes quadrature components of the received symbol.

A diagnostic method implemented by the QAM receiver is also provided.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1 shows a conventional QAM receiver;

FIG. 2 shows an ideal 64-QAM constellation distributed in a decision grid;

FIG. 3a to 3d show various erroneous readings in the constellation generated by the conventional QAM receiver;

FIG. 4 shows an embodiment of a QAM receiver according to the invention;

FIG. 5a to 5c show embodiments of decision grid diagnosis;

FIG. 6 is a flowchart of a diagnostic method according to the invention.

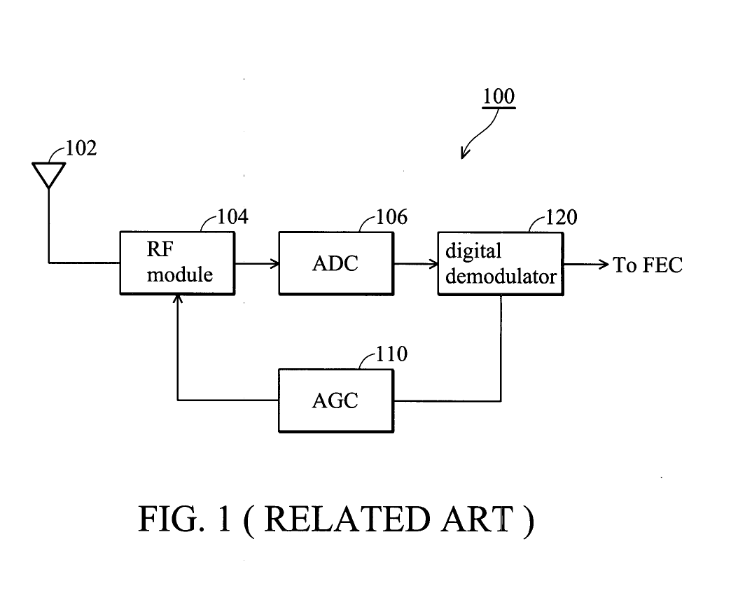

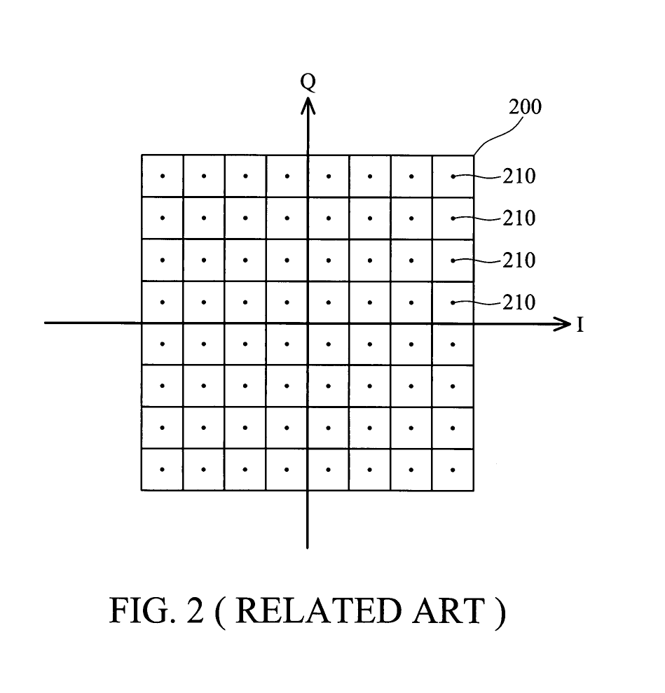

### DETAILED DESCRIPTION OF THE INVENTION

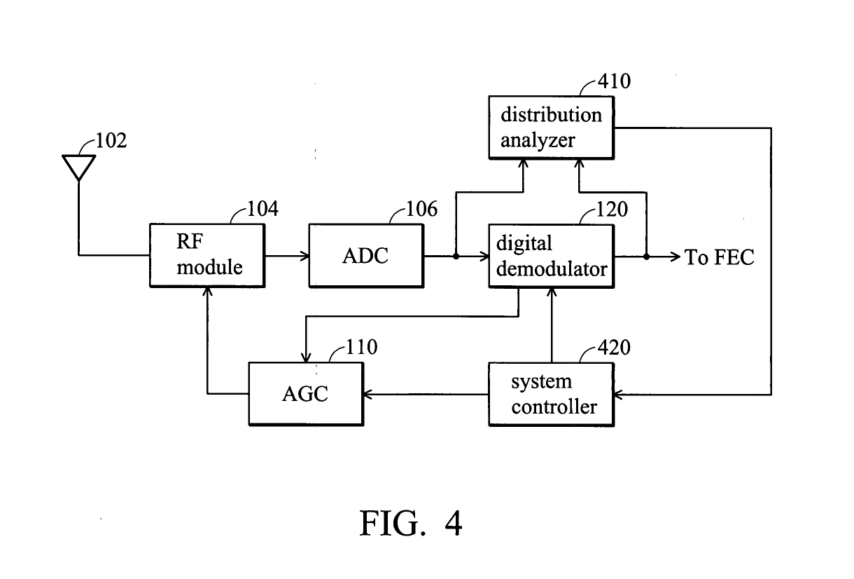

FIG. 4 shows an embodiment of a QAM receiver according to the invention. A distribution analyzer 410 is provided, coupled to the output of ADC 106 and digital demodulator 120. Signals therefrom are mapped to a constellation and analyzed to diagnose whether the described symptoms occur. A system controller 420 is coupled to the distribution analyzer 410, sending corresponding signals to adjust the system components where the symptoms originate.

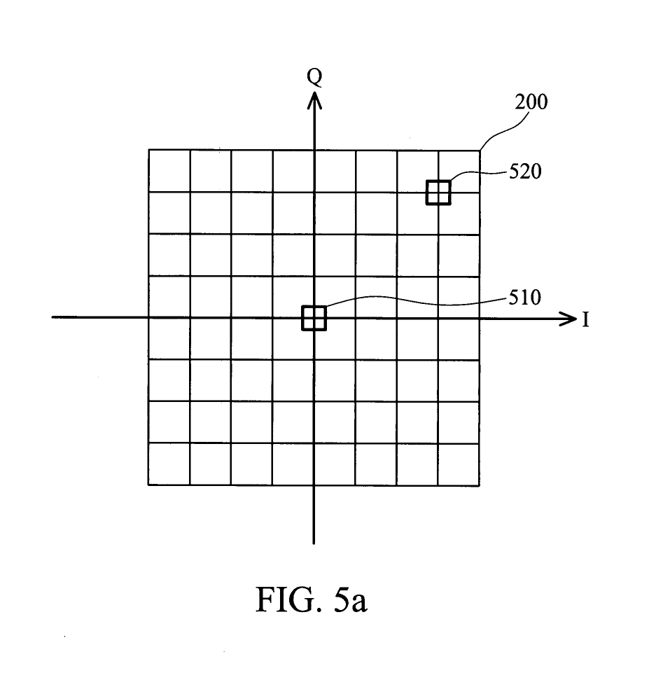

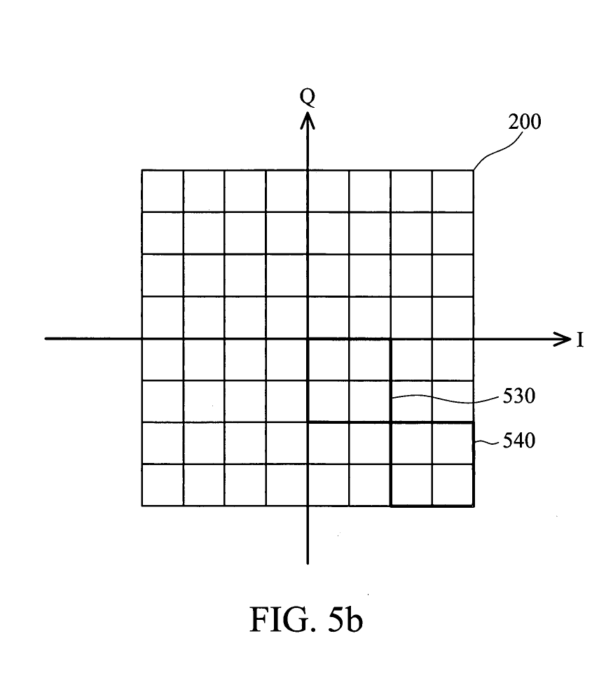

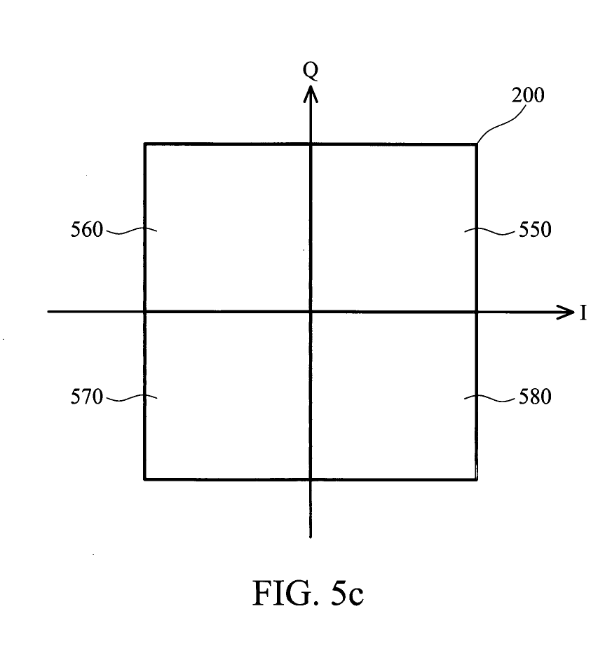

FIG. 5a to 5c show embodiments of decision grid diagnosis. In FIG. 5a, regions 510 and 520 are provided as logical windows to statistic symbols distributed therein. Region 510 is centered at the origin of the coordinate, covering an area expected to have no symbol distribution. Region 520 is selected to cover an area centered at an intersection point of four adjacent cells at a corner, having identical area with the region 510. Regions 510 and 520 are intended to observe regions expected to have zero values. As a result, a center value and a corner value are obtained thereby. By measuring the ratio of the center and corner values, a rotation can be detected. Since regions 510 and 520 are expected to be zero values, any value represents a potential error. If the region 520 obtains a corner value several times greater that the center value, the constellation is considered to be rotating. SNR is also observable via regions 510 and 520. If the radius r of a spot 210 grows due to bad SNR, the symbol distribution overlaps with boundaries of regions 510 and 520, the observed center and corner values correspondingly represent a substantially identical level exceeding a corresponding threshold.

FIG. 5b shows two windows for diagnosing AGC. A region 530 frames four cells adjacent to the coordinate origin, and a region 540 frames four cells aligned to a corner side of the decision grid 200. An inner value and an outer value are respectively obtained for comparison. When correctly normalized, the constellation is the same size as the decision grid 200, such that symbol distribution in the regions 530 and 540 are substantially identical. If the AGC 110 has not yet converged or is failing, values in the regions 530 and 540 reflect the symptoms of expanded or reduced constellations 320 and 325. If the outer value is several times greater than the inner value, the constellation has increased and the AGC 110 is over-amplified. Conversely, if the inner value is several times greater than the outer value, the constellation has reduced, and AGC 110 is under-amplified.

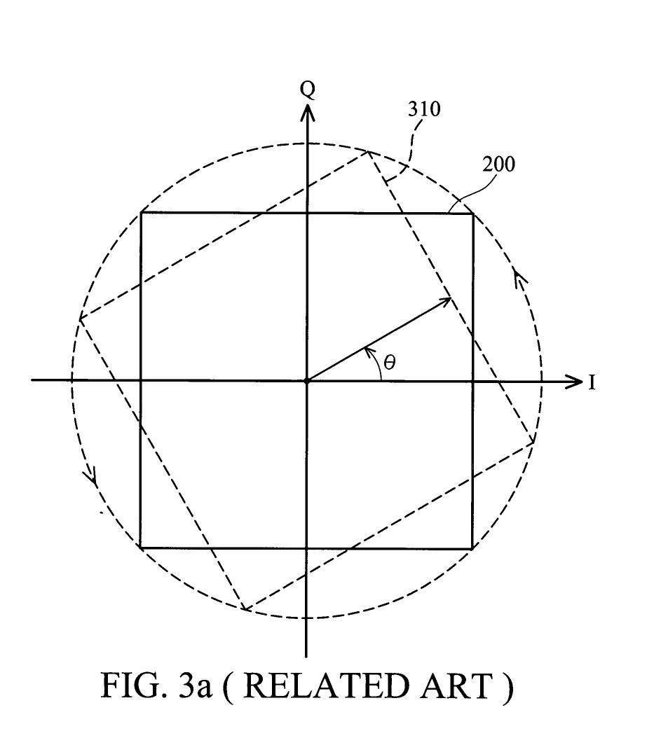

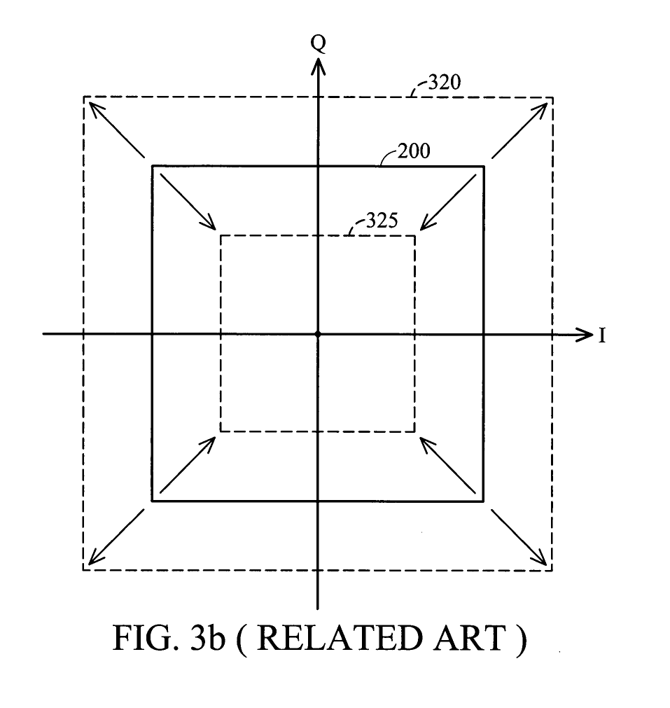

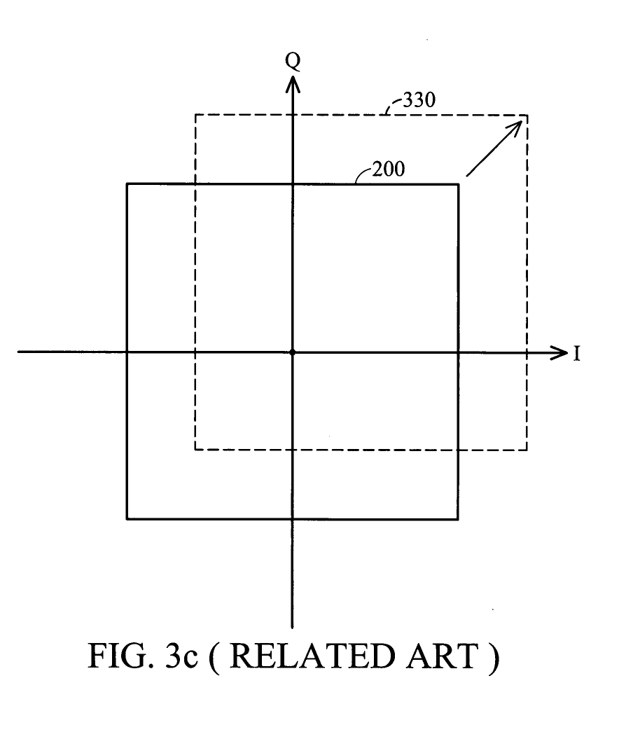

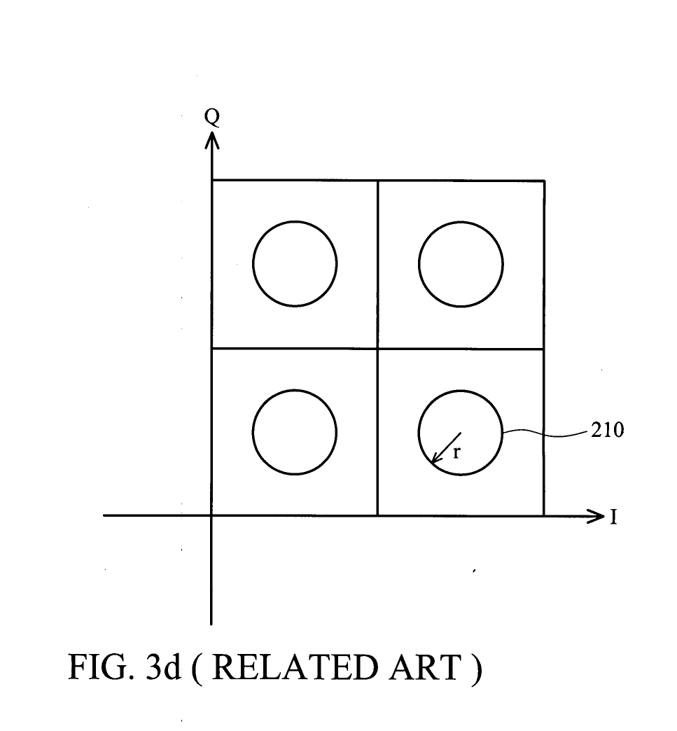

FIG. 5c shows four windows each observing a quadrant. The decision grid 200 is based on a coordinate system comprising four quadrants. When DC offset occurs, a constellation 330 may offset as shown in FIG. 3c, whereby unbalanced distributions are reflected in four values observed by the region 550 to 580 in the decision grid 200. If the constellation is offset upward, values obtained by the regions 550 and 560 exceed those obtained by regions 570 and 580. Similarly, if the constellation is offset rightward, values obtained by regions 550 and 580 exceed those obtained by regions 560 and 570.

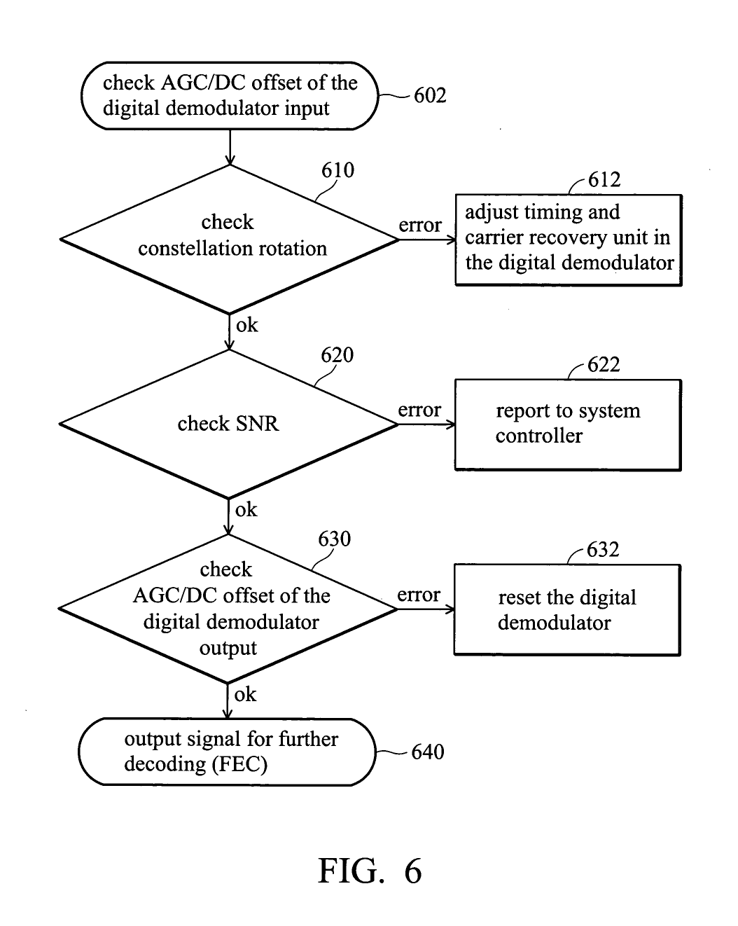

FIG. 6 is a flowchart of a diagnostic method according to the invention. Based on constellation analysis, an. embodiment of a diagnostic method is provided as follows. In step 602, the digital demodulator 120 distribution analyzer 410 first checks the output from ADC 106 to ensure that AGC 110 amplification and DC offset are normal. In step 610, the distribution analyzer 410 analyzes the output from digital demodulator 120 to check constellation rotation. If the constellation is rotating, the process proceeds to step 612 and the distribution analyzer 410 sends a signal to the system controller 420, whereby the system controller 420 adjusts timing and carrier recovery in the digital demodulator 120 accordingly. After checking the rotation in step 610, in step 620 the distribution analyzer 410 checks SNR of the received symbols according to the constellation. At an error the process goes to step 622, wherein the system controller 420 determines whether to reset the QAM receiver. In step 630, the distribution analyzer 410 reexamines whether the AGC 110 is operating normally, and determines whether another DC offset has occurred in the digital demodulator 120. At an error the process goes to step 632, wherein the system controller 420 resets the digital demodulator 120. If the diagnosis finds no problem, the signal is output for forward error coding (FEC) such as trellis decoding or RS decoding.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A diagnostic method for a Quadrature Amplitude Modulation (QAM) receiver demodulating received symbols into a constellation, comprising:
providing a decision grid for constellation analysis;
adjusting the QAM receiver based on the constellation analysis; wherein:
the decision grid is a square comprising a plurality of cells, each corresponding to
a digital value, in which a coordinate is formed by a horizontal axis crossing a vertical axis at the square center to generate four partitions as four quadrants;
the horizontal axis denotes inphase components of the received symbol; and
the vertical axis denotes quadrature components of the received symbol.

2. The diagnostic method as claimed in claim 1, wherein the constellation analysis is one of the followings:
determining whether the constellation is rotating by the decision grid;
determining the signal-to-noise ratio (SNR) of the received symbols according to the constellation analysis;
determining whether the gain of the received symbols is correct according to the constellation analysis; and
determining whether a DC offset has occurred according to the constellation
analysis.

3. The diagnostic method as claimed in claim 2, wherein:
the decision grid comprises a first region and a second region having identical area;
the first region is centered at the square center;
the second region is inside a square corner; and
the rotation determination comprises:
accumulating symbols distributed in the first and second regions within a period of time, whereby a first value and a second value are respectively obtained;
calculating a ratio of the first to second value; and
if the ratio of the first to second values is lower than a rotation threshold, notifying the QAM receiver that the constellation is rotating.

4. The diagnostic method as claimed in claim 3, further comprising compensating timing and phase offsets of the received symbols according to the rotation determination result.

5. The diagnostic method as claimed in claim 3, wherein the determination of the SNR of the received symbols comprises:
estimating the first and second values; and
if the first and second values exceed a SNR threshold, notifying the QAM receiver that the SNR of the received symbols is too low.

6. The diagnostic method as claimed in claim 2, wherein:
the decision grid comprises a first region and a second region having identical area;
the first region is aligned to the horizontal and vertical axes;
the second region is aligned to the corner edge of the decision grid; and
the gain determination comprises:
accumulating symbols distributed in the first and second regions within a period of time, such that a first value and a second value are respectively obtained;
calculating a ratio of the first to second values; and
if the ratio of the first and second values is lower than a first threshold, notifying the QAM receiver that the gain has overflowed; and
if the ratio of the first to second values exceeds a second threshold, acknowledging the QAM receiver that the gain is underflow,
wherein the first threshold is lower than the second threshold.

7. The diagnostic method as claimed in claim 6, wherein the QAM receiver comprises an auto gain controller for normalizing the power of received symbols, and the diagnostic method further comprises adjusting the auto gain controller according to the gain determination result.

8. The diagnostic method as claimed in claim 2, wherein the DC offset determination comprises:
individually accumulating symbols distributed in the four quadrants within a period of time, whereby four values are respectively obtained;
calculating a ratio of the upper and lower quadrants to determine a quadrature DC offset; and
calculating a ratio of the left and right quadrants to determine an inphase DC offset.

9. The diagnostic method as claimed in claim 8, wherein the DC offset determination further comprises if the ratio of upper to lower quadrants is lower than a first threshold, or if the ratio of the upper to lower quadrants exceeds a second threshold, acknowledging the QAM receiver that a quadrature DC offset has occurred; wherein the first threshold is lower than the second threshold.

10. The diagnostic method as claimed in claim 8, wherein the DC offset determination further comprises, if the ratio of left to right quadrants is lower than a first threshold, or if the ratio of the left to right quadrants exceeds a second threshold, notifying the QAM receiver that an inphase DC offset has occurred; wherein the first threshold is lower than the second threshold.

11. A Quadrature Amplitude Modulation (QAM) receiver demodulating received symbols into a constellation, comprising:
a radio frequency (RF) module, receiving and demodulating radio signals into received symbols;
an analog to digital converter (ADC), coupled to the RF module, generating digital signals from the received symbols;
an auto gain controller (AGC), normalizing signal amplitudes in the RF module;
a digital demodulator, performing synchronization and equalization to decode the digital signals and generate a constellation;
a distribution analyzer, coupled to the output of the ADC and the digital demodulator, using a decision grid to analyze the constellation;
a system controller, coupled to the distribution analyzer, adjusting the AGC and digital demodulator according to the constellation analysis.

12. The QAM receiver as claimed in claim 11, wherein the distribution analyzer:
determines whether the constellation is rotating by the decision grid;
determines the signal-to-noise ratio (SNR) of the received symbols according to the constellation analysis;
determines whether the gain of the received symbols is correct according to the constellation analysis; or
determines whether a DC offset occurs according to the constellation analysis;
wherein:
the decision grid is a square comprising a plurality of cells, each corresponding to a digital value, in which a coordinate is formed by a horizontal axis crossing a vertical axis at the square center to generate four partitions as quadrants;
the horizontal axis denotes inphase components of the received symbol; and
the vertical axis denotes quadrature components of the received symbol.

13. The QAM receiver as claimed in claim 12, wherein:
the decision grid comprises a first region and a second region having identical area;
the first region is centered at the square center;
the second region is inside a square corner;
the distribution analyzer determines the constellation rotation by:
accumulating symbols distributed in the first and second regions within a period of time, such that a first value and a second value are respectively obtained; and
calculating a ratio of the first to second value; and
if the ratio of the first to second values is lower than a rotation threshold, the system controller notifies the QAM receiver that the constellation is rotating.

14. The QAM receiver as claimed in claim 13, wherein the system controller drives the digital demodulator to compensate timing and phase offsets of the received symbols based on the constellation rotation determination result.

15. The QAM receiver as claimed in claim 13, wherein:
the distribution analyzer determines the SNR of the received symbols by estimating the first and second values; and
if the first and second values exceed a SNR threshold, the distribution analyzer notifies the QAM receiver that the SNR of the received symbols is too low.

16. The QAM receiver as claimed in claim 12, wherein:
the decision grid comprises a first region and a second region having a
substantially identical area;
the first region is aligned to the horizontal and vertical axes;
the second region is aligned to the corner edge of the decision grid;
the distribution analyzer further performs gain determination by:
accumulating symbols distributed in the first and second regions within a period of time, such that a first value and a second value are respectively obtained; and
calculating a ratio of the first and second value;
if the ratio of the first and second values is lower than a first threshold, the distribution analyzer notifies the QAM receiver that the gain is overflow;
and
if the ratio of the first and second values exceeds a second threshold, the distribution analyzer notifies the QAM receiver that the gain is underflow;
wherein the first threshold is lower than the second threshold.

17. The QAM receiver as claimed in claim 16, wherein the system controller adjusts the amplification of AGC to normalize the power of received symbols according to the gain determination result.

18. The QAM receiver as claimed in claim 12, wherein the distribution analyzer determines the DC offset by:
individually accumulating symbols distributed in the four quadrants within a period of time, such that four values are respectively obtained;
calculating a ratio of the upper and lower quadrants to determine a quadrature DC offset; and
calculating a ratio of the left and right quadrants to determine an inphase DC offset.

19. The QAM receiver as claimed in claim 18, wherein:
if the ratio of the upper and lower quadrants is lower than a first threshold, or if the ratio of the upper and lower quadrants is exceeding a second threshold, the distribution analyzer notifies the QAM receiver that a quadrature DC offset has occurred; and
the first threshold is lower than the second threshold.

20. The QAM receiver as claimed in claim 18, wherein:
if the ratio of the left and right quadrants is lower than a first threshold, or if the ratio of the left to right quadrants is exceeding a second threshold, the distribution analyzer notifies the QAM receiver that an inphase DC offset has occurred; and
the first threshold is lower than the second threshold.
